(19) United States
(12) Patent Application Publication
(10) Pub. No.: US 2014/0017870 A1
(43) Pub. Date: Jan. 16, 2014

(54) Method for Inhibiting Programming Disturbance of Flash Memory

(71) Applicants: Yimao Cai, Beijing (CN); Ru Huang, Beijing (CN)

(72) Inventors: Yimao Cai, Beijing (CN); Ru Huang, Beijing (CN)

(73) Assignee: PEKING UNIVERSITY, Beijing (CN)

(21) Appl. No.: 13/510,618

(22) PCT Filed: Oct. 28, 2011
(86) PCT No.: PCT/CN11/81484

§ 371 Date: Jun. 7, 2012

(30) Foreign Application Priority Data
Apr. 6, 2011 (CN) 201110084807.4

(51) Int. Cl. H01L 21/265

(52) U.S. Cl. CPC H01L 21/26586
USPC 438/302

(57) ABSTRACT

Disclosed herein is a method for inhibiting a programming disturbance of a flash memory, which relates to a technical field of a non-volatile memory in ultra-large-scale integrated circuit fabrication technologies. In the present invention, an dopant gradient of a PN junction between a substrate and a drain is reduced by adding a step of performing an angled ion implantation of donor dopants into a standard process for a flash memory, so that an electric field of the PN junction between the substrate and the drain is reduced, and consequently the programming disturbance is inhibited. Meanwhile, a dopant gradient of the PN junction between a channel and the drain is maintained, so that an electric field of the PN junction between the channel and the drain, which is necessary for programming, is maintained, and thus the programming efficiency and the programming speed can be ensured. The programming disturbance can be effectively inhibited without increasing numbers of masks used for photolithography according to the invention, thus the present invention is significantly advantageous to the improvement of the flash memory reliability.

### FIELD OF THE INVENTION

The present invention relates to a technical filed of a non-volatile memory in ultra-large-scale integrated circuit fabrication technologies, and particularly to a method for inhibiting programming disturbance of a flash memory.

### BACKGROUND OF THE INVENTION

Non-volatile memory , especially flash memory, is widely used in various products such as mobile phones, laptops, palmtops, storage devices such as solid state hard drives and communication device, due to the data retaining capability under power-off condition and the merit of multiple data erasing and writing cycles. Among them, NOR flash memory is frequently used in chips for storing codes in mobile terminals, like mobile phones, because of the high speed for random accessing. conventional NOR flash memory, however, is typically an n-channel memory cell, where programming is performed in a mechanism of channel hot electron injection which needs a high bit line voltage (typically 4-5V). Meanwhile, it is necessary to form a relatively strong electric field between the channel and the drain so that sufficient energy can be gained by electrons in the channel to inject into the data storage layer. For a conventional method, with the highly N-doped drain and highly P-doped substrate and channel, an abrupt PN junction is formed. Hence a relatively strong electric field is obtained (see FIG. 1). As a gate length of a flash memory is reduced with each technology generation, the P-type doping concentration for the channel has been increased dramatically, resulting in a continuous raise of the electric field in the PN junction between the channel/substrate and the drain. In addition, since the bit line voltage for programming is difficult to be lowered, a problem of programming disturbance is getting more serious. A schematic view of the programming disturbance is shown in FIG. 2. During programming, a high electric potential is applied to a word line of a selected memory cell, and another high electrical potential is applied to the bit line. Since the same word line or bit line is to be coupled to multiple memory cells, the programming disturbance associated with the electric field of the PN junction occurs in those memory cells commonly coupled to the same bit line (applied with a high electric potential) while coupled to different word lines.

Since the programming disturbance has an impact on the reliability of flash memory, how to inhibit programming disturbance based on structures, fabrication processes and circuits has become an important subject of the fabrication and development of the flash memories. For example, the doping concentration of the drain may be effectively reduced by using a lightly doped drain (LDD) process, so that the ion concentration gradient of the PN junction between the channel and the drain is reduced, and thus the electric field can be reduced to inhibit the program disturbance. However, the method may result in sharp reduction in the electric filed in the PN junction between the channel and the drain of the selected memory cell, which reduce the speed and efficiency of programming.

In a word, method of obtaining a flash memory device that may effectively inhibit programming disturbance via a simple process is one of the demanding-prompt solutions in the flash memory technology.

### SUMMARY OF THE INVENTION

A method for a flash memory is provided in the present invention, which is capable of inhibiting programming disturbance in flash memory and compatible with conventional process without increasing numbers of masks for photolithography, and thus has little influence on the process cost. In the method according to the invention, a step of performing an angled ion implantation for donor dopants is added and a structure of the flash memory as well as other processes thereof are the same as the conventional process for flash memory, so that the dopants gradient of the PN junction between the substrate and the drain is reduced, and thus the electric field of the PN junction between the substrate and the drain is reduced, and consequently the programming disturbance is inhibited. Meanwhile, the dopants gradient of the PN junction between the channel and the drain is maintained, so that an electric field of the PN junction between the channel and the drain, which is necessary for programming, is maintained, and thus the efficiency and speed of programming can be ensured.

The object mentioned above is achieved by the following technical solution.

A method for inhibiting programming disturbance of flash memory includes: adding a step of ion implantation into a standard method for an n-channel flash memory, that is, an angled ion implantation of donor dopants of medium dose is induced after performing an implantation for source/drain and forming a sidewall during the standard method. The angle, dose and energy for the ion implantation are selected within a certain range so that the implanted donor dopants are substantially concentrated on the PN junction between the substrate under the channel and the drain. After performing an annealing process to diffuse the dopants, the P-type dopants around the PN junction between the substrate and the drain can be compensated by the implanted dopants effectively, so that the electric field of the PN junction between the substrate and the drain is reduced and thus the programming disturbance is reduced.

The above-mentioned dopants implanted during the ion implantation of donor dopants may be phosphorous, arsenic, other pentavalent elements or compounds thereof. Preferably, a dose range for implanting is 1×10¹⁶ cm²˜5×10¹⁷ cm²; an angle range for implanting is 15°˜45°; and an energy range for implanting is 30 keV˜50 keV.

The difference between the process according to the invention and the lightly doped drain (LDD) process lies in that, in the latter, a lightly doped drain is used to form a gradually-changed ultra-shallow junction between the surface channel and the drain (see FIG. 3) in order to reduce the electric field between the surface channel and the drain. Thus, in the method according to the present invention, the donor dopants are implanted prior to form a sidewall of the memory cell, with an angle of 0 degree and an energy based on the device size, which is preferably as small as possible (typically smaller than 20 keV) according to the shrink of the device size. In the present invention, however, a gradually-changed PN junction between the substrate under the channel and the drain is formed in order to maintain the abrupt PN junction between the surface channel and the drain. Therefore, the ion implantation, in which an angled implantation and certain energy are necessary, is performed after forming the sidewall.

The difference between the invention and a pocket implanting process commonly used in the standard CMOS process lies in that, the purpose of the pocket process is to enhance the concentration gradient between the channel/substrate and the drain, and therefore the type of the implanted dopants is the same as the dopant type of the substrate (see FIG. 4). For example, the dopants implanted to the n-channel flash memory are acceptor dopants, whereas the implanted dopants in the invention are donor dopants.

In comparison with the prior art, the method for inhibiting programming disturbance of flash memory according to the invention have the following advantages. First of all, the process is easily to be performed by adding a further step into the standard process flow without increasing numbers of masks used for photolithography. Moreover, only the electric field of the PN junction between the substrate and the drain is reduced, while there is no impact on the electric field between the surface channel and the drain, and consequently the programming speed is not affected.

Therefore, the above-mentioned method for inhibiting programming disturbance of flash memory is an economic and highly-effective solution for improving the reliability of the flash memory.

### BRIEF DESCRIPTION OF THE DRAWINGS

The above and other objects, features and advantages of the present invention will become more apparent by describing in detail with reference to the accompanying drawings. Like reference numerals refer to like parts throughout the various figures. The drawings do not necessarily present the real scale, with purpose of illustrating the spirit of the invention.

FIG. 1 is a schematic view showing a structure of an n-channel NOR-type flash memory cell, in which, reference sign “1” denotes the control gate; reference sign “2” denotes the charge storage layer; reference sign “3” denotes the source; reference sign “4” denotes the drain; reference sign “5” denotes the substrate; and reference sign “6” denotes the channel.

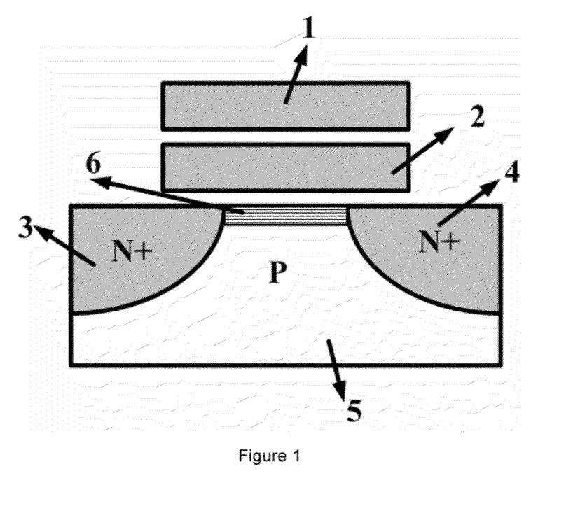

FIG. 2 is a schematic view showing the programming disturbance occurring during programming a NOR-type flash memory array, in which,

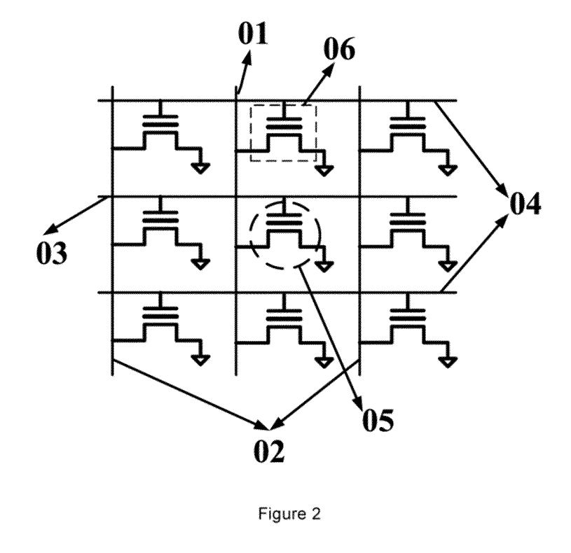

reference sign “01” denotes a selected bit line; reference sign “02” denotes an unselected bit line; reference sign “03” denotes a selected word line; reference sign “04” denotes an unselected word line; reference sign “05” denotes a memory cell selected to be programmed; and reference sign “06” denotes a memory cell subject to the programming disturbance associated with an electric field of a PN junction at a drain.

FIG. 3 is a schematic view showing a lightly doping drain (LDD) process, in which,

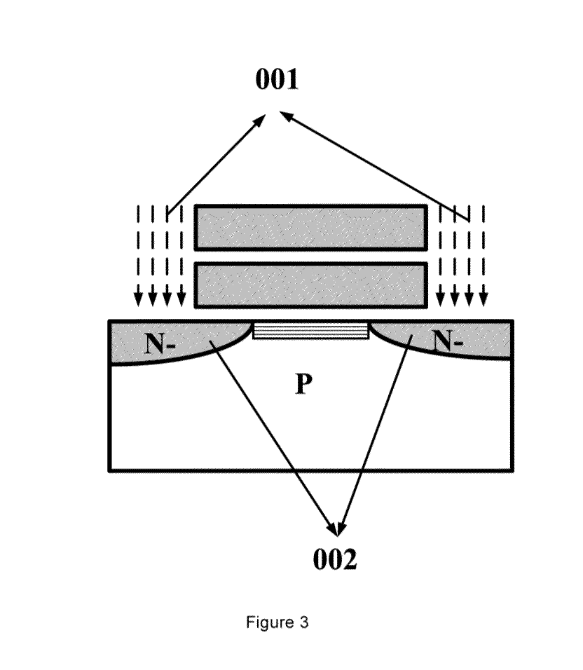

reference sign “001” denotes lightly doping a drain by an ion implantation process, wherein the implanted dopants are donor dopants; and reference sign “002” denotes N regions of low concentration connected to a channel, formed through lightly doping a drain region by an ion implantation process.

FIG. 4 is a schematic view showing a pocket doping process for a memory device, in which,

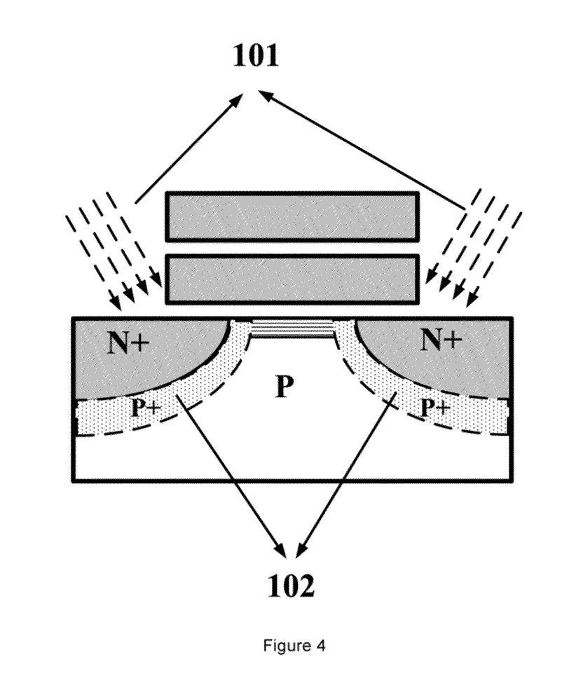

reference sign “101” denotes an ion implantation process by pocket doping, wherein the implanted dopants are acceptor-type dopants; and reference sign “102” denotes P⁺ regions around the source/drain region, formed through the pocket doping.

FIG. 5 is a schematic view showing a process for inhibiting the programming disturbance of flash memory according to the invention, in which, reference sign “201” denotes sidewalls of a memory cell; reference sign “202” denotes an ion implantation process provided by the invention, where the dopants are donor dopants; and reference sign “203” denotes a distribution of the donor dopants formed at a PN junction between a substrate and the source/drain, by the ion implantation of the invention.

### DETAILED DESCRIPTION OF THE EMBODIMENTS

The above objects, features and advantages of the present invention will become more apparent by describing in detail embodiments thereof with reference to the accompanying drawings.

Hereinafter, details will be described to make the invention fully understandable. However, the invention may be implemented through other ways that are different from the embodiments described herein, and similar extension may be made by those skilled in the art without departing from the spirit of the invention. Therefore, the invention is not limited to the embodiments described below.

Further, the invention is described in detail with reference to schematic views. For the purpose of convenience, cross-sectional views of a device will be partially exaggerated instead of following a regular scale during describing the embodiments of the invention. Also, the schematic views are only exemplary examples, which should not be conveyed as to limit the scope of the invention. Moreover, a three-dimensional space scale including a length, a width and a depth should be contained in a practical manufacture.

As introduced in the background of the invention, it is found after researches by the inventor that, if a concentration gradient of a PN junction between a substrate and a drain of a NOR-type flash memory is reduced, a programming disturbance electric field may be decreased effectively, so that the programming disturbance may be inhibited to dramatically improve reliability of the NOR-type flash memory.

Based on that, a novel method for inhibiting the programming disturbance of the flash memory is provided by the invention, wherein the programming disturbance electric field may be inhibited and the reliability of the flash memory may be dramatically improved through the method in which an ion implantation process is added into a standard process flow.

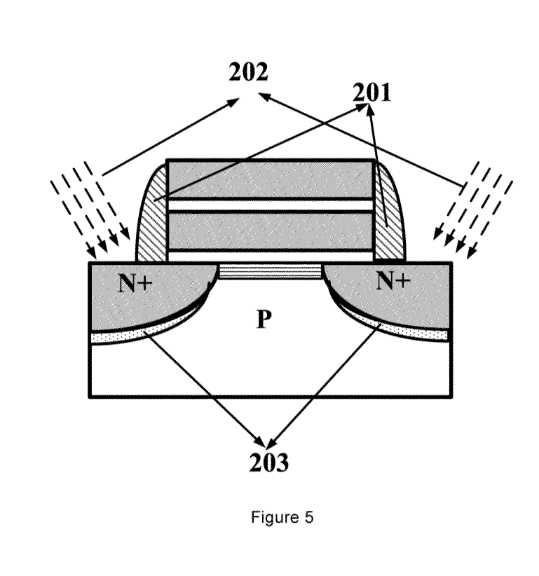

A process for inhibiting the programming disturbance of flash memory according to the invention is shown in FIG. 5, in which reference sing “201” denotes sidewalls of a memory cell; reference sing “202” denotes an ion implantation process provided by the invention, where the dopants are donor dopants; and reference sing “203” denotes a distribution of the donor dopants formed at a PN junction between a substrate and a source/drain, according to the ion implantation of the invention.

Hereinafter, a preferable embodiment of a process for inhibiting the programming disturbance of the flash memory according to the invention will be described in detail with reference to FIG. 5.

(1) A standard process flow for an NOR-type flash memory is used till the process according to the invention.

(2) After sidewalls are formed through the standard process flow, an ion implantation of donor dopants according to the invention is performed (as shown in FIG. 5).

(3) A dose range of the implanted dopants is 1×10¹⁶ cm²˜5×10¹⁷ cm².

(4) An angle for implanting the dopants is 15°˜45°.

(5) An energy for implanting dopants is 30 keV˜50 keV.

(6) The dopants are implanted so that the implanted donor dopants are substantially distributed in the vicinity of a PN junction between a substrate under a surface channel and a drain.

(7) A standard process flow for an NOR-type flash memory is used after the process according to the invention is completed.

A preferable embodiment of the invention is described above; however, the invention should not be limited thereby in any manner.

While the invention is disclosed as the preferable embodiment described above, the invention is not limited thereto. Various possible changes and modifications, or their equivalents can be made by those skilled in the art by means of the method and technical contents disclosed above, without departing from the scope of the invention. Therefore, any changes and modifications, or their equivalents by means of the technical contents of the invention without departing form the spirit of the invention should be within the scope defined in claims.

What is claimed is:

1. A process for inhibiting a programming disturbance of a flash memory, wherein, a step of ion implantation is introduced in a standard process for the flash memory, wherein an angled ion implantation is performed after performing an implantation for a source/drain and forming sidewalls during the standard process, so that the implanted dopants are concentrated on a PN junction between a substrate under a channel and the source/drain.

2. The method according to claim 1, wherein, the implanted dopants are donor dopants for silicon, such as arsenic, phosphorous and compounds thereof.

3. The ion implantation process according to claim 2, wherein, an energy range for the ion implanting is 30 keV˜50 keV.

4. The ion implantation process according to claim 2, wherein, an angle range for the ion implanting is 15°˜45°.

5. The ion implantation process according to claim 2, wherein, a dose range for ion the implanting is 1×10¹⁶ cm²˜5×10¹⁷ cm².
